(19) United States
(12) Patent Application Publication
(10) Pub. No.: US 2026/0134921 A1
(43) Pub. Date: May 14, 2026

(54) METHOD FOR OPERATING MEMORY DEVICE

(71) Applicant: MACRONIX INTERNATIONAL CO., LTD., Hsinchu (TW)

(72) Inventors: Shih-Chung LEE, Katsuradaiminami (JP); Chi-Yuan CHIN, Hsinchu City (TW)

(21) Appl. No.: 18/941,129

(22) Filed: Nov. 8, 2024

(51) Int. Cl. G11C 16/10; G11C 16/34

(52) U.S. Cl. CPC G11C 16/102; G11C 16/349

(57) ABSTRACT

A method for operating a memory device is provided. The memory device to be operated includes a 0^{th} word line to a M^{th} word line connected to memory cells of a block of the memory device. The method includes programming the block from the 0^{th} word line to the M^{th} word line for N1 program-erase cycles and programming the block from the M^{th} word line to the 0^{th} word line for N2 program-erase cycles, wherein N1 and N2 are positive integers.

### TECHNICAL FIELD

This disclosure relates to a method for operating a memory device. More particularly, this disclosure relates to a method involving programming a block of a memory device with different program sequences.

### BACKGROUND

Reliability of a NAND memory device is better when cells of the memory device stay at programmed states longer, before the cells are erased and re-programmed with new data. On the contrary, reliability of the cells becomes worse when the cells stay at erased states for a long period of time before the cells are programmed. In other words, keeping a block of the memory device at a programmed state is preferred than at an erased state. Therefore, in order to keep the reliability, a block of a NAND product is only erased right before new data are allocated to the block.

However, in some products, such as an enterprise SSD (eSSD), open blocks are often present. Typically, cells in a block are programmed with a program sequence starting from a 0^{th} word line. As such, in an open block, cells controlled by word lines indicated by smaller numbers may have been programmed, while cells controlled by word lines indicated by larger numbers may stay at erased stats for a longer period, such as about one hour, before the blocks are fully programmed and closed. The cells controlled by word lines indicated by larger numbers thus suffer worse degradation than the cells controlled by word lines indicated by smaller numbers due to the longer stay at the erased states, which creates an unbalance reliability issue within a block. Throughout the program-erase cycles, the unbalance reliability issue becomes more pronounced.

### SUMMARY

This disclosure provides a method for operating a memory device for addressing the unbalance reliability issue as described above.

The memory device to be operated comprises a 0^{th} word line to a M^{th} word line connected to memory cells of a block of the memory device. The method according to the disclosure comprises programming the block from the 0^{th} word line to the M^{th} word line for N1 program-erase cycles and programming the block from the M^{th} word line to the 0^{th} word line for N2 program-erase cycles, wherein N1 and N2 are positive integers.

### BRIEF DESCRIPTION OF THE DRAWINGS

FIG. 1 shows a flow diagram of a method for operating a memory device according to the disclosure.

FIG. 2 shows an example of a memory device to operated.

FIG. 3 shows an example of the method according to the disclosure.

FIG. 4 shows another example of the method according to the disclosure.

FIG. 5 shows still another example of the method according to the disclosure.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

Various embodiments will be described more fully hereinafter with reference to accompanying drawings. The description and the drawings are provided for illustrative only, and not intended to result in a limitation. For clarity, the elements may not be drawn to scale. In addition, some elements and/or reference numerals may be omitted from some drawings. It is contemplated that the elements and features of one embodiment can be beneficially incorporated in another embodiment without further recitation.

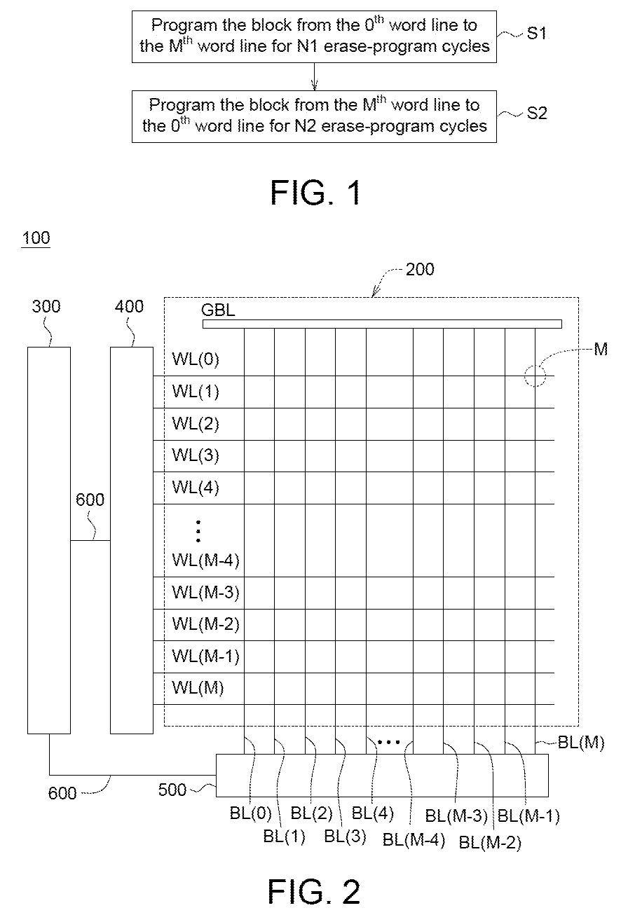

In this disclosure, a method for operating a memory device is provided. FIG. 1 shows a flow diagram of a method for operating a memory device according to the disclosure. FIG. 2 shows an example of a memory device 100 to operated. The memory device 100 can be a NAND memory device typically with open blocks, such as an enterprise SSD (eSSD).

The memory device 100 comprises a 0^{th} word line WL(0) to a M^{th} word line WL(M) connected to memory cells M of a block 200 of the memory device 100. More particularly, as shown in FIG. 2, the block 200 comprises a plurality of memory cells M defined by cross points of a 0^{th} bit line BL(0) to a M^{th} bit line BL(M) and the 0^{th} word line WL(0) to the M^{th} word line WL(M). In the accompanying drawings, only a global bit line GBL and several bit lines BL(0) to BL(4) andBL(M-4) to BL(M), and several word lines WL(0) to WL(4) andWL(M-4) to WL(M) are exemplarily shown, and the other signal lines for the memory array 200 are omitted for clarity of the drawings. It is understood that M is a positive integer and a total number of the bit lines BL(0) to BL(M) and a total number of the word lines WL(0) to WL(M) can be changed according to the device design. The memory device 100 can further comprise a controller 300 for controlling operations of the memory device 100. The memory device 100 can further comprise a word line driver 400 coupled to the word lines WL(0) to WL(M) and a bit line driver 500 coupled to the bit lines BL(0) to BL(M). The controller 300 is coupled to the word line driver 400 and the bit line driver 500 through signal lines 600, and thus further coupled to the word lines WL(0) to WL(M) and the bit lines BL(0) to BL(M) to control the block 200. In order to clearly illustrate the method according to the disclosure, the following details will be described in conjunction with the memory device 100, and particular with the block 200.

Referring back to FIG. 1, the method for operating the memory device 100 comprises a step S1 and a step S2. In the step S1, the block is programmed from the 0^{th} word line WL(0) to the M^{th} word line WL(M) for N1 program-erase cycles, and in the step S2, the block 200 is programmed from the M^{th} word line WL(M) to the 0^{th} word line WL(0) for N2 program-erase cycles, wherein N1 and N2 are positive integers. It is understood that each time the block 200 is erased and re-written, that is one program-erase cycle (P/E cycle). A total number of program/erase cycles of each block in a SSD is fixed, and thus P/E cycle can reflect the lifetime of a SSD.

The method can further comprise switching a program sequence of the block 200 using the controller 300 of the memory device 100 between said programming the block 200 from the 0^{th} word line WL(0) to the M^{th} word line WL(M) for N1 program-erase cycles and said programming the block 200 from the M^{th} word line WL(M) to the 0^{th} word line WL(0) for N2 program-erase cycles. A frequency of the switching can be a part of a firmware in the controller 300. The firmware can comprise two set of operation codes for a program sequence from the 0^{th} word line WL(0) to the M^{th} word line WL(M) and a program sequence from the M^{th} word line WL(M) to the 0^{th} word line WL(0), respectively. During said programming the block 200 from the 0^{th} word line WL(0) to the M^{th} word line WL(M) for N1 program-erase cycles, the controller 300 controls the programming of the block 200 using the set of operation code for the program sequence from the 0^{th} word line WL(0) to the M^{th} word line WL(M). During said programming the block 200 from the M^{th} word line WL(M) to the 0^{th} word line WL(0) for N2 program-erase cycles, the controller 300 controls the programming of the block 200 using the set of operation code for the program sequence from the M^{th} word line WL(M) to the 0^{th} word line WL(0).

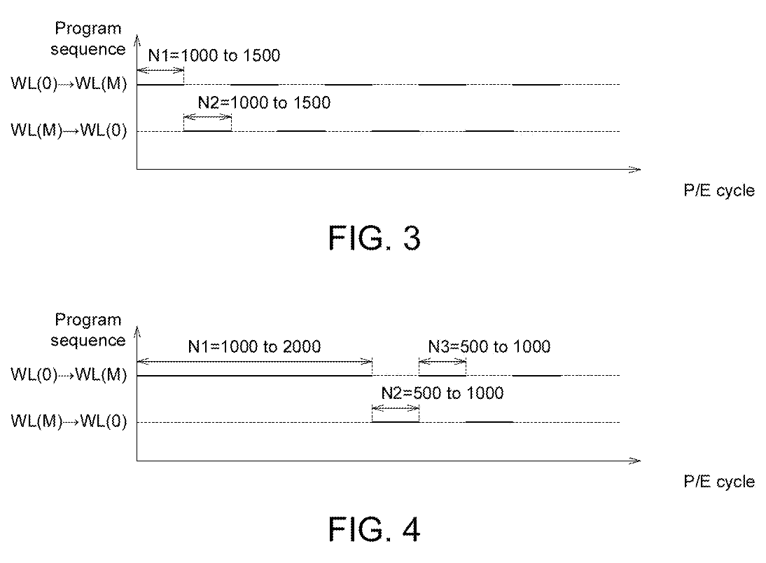

FIG. 3 shows a specific example of the method according to the disclosure. In this example, the program sequence of the block 200 is switched in a fixed frequency. As such, the method can further comprise recording a cycle number during the N1 program-erase cycles in the controller 300 of the memory device 100 during said programming the block 200 from the0^{th} word line WL(0) to the M^{th} word line WL(M) for N1 program-erase cycles and recording a cycle number during the N2 program-erase cycles in the controller 300 during said programming the block 200 from the M^{th} word line WL(M) to the 0^{th} word line WL(0) for N2 program-erase cycles, and switching the program sequence of the block 200 between from the 0^{th} word line WL(0) to the M^{th} word line WL(M) and from the M^{th} word line WL(M) to the 0^{th} word line WL(0) when the cycle number during the N1 program-erase cycles or the cycle number during the N2 program-erase cycles reaches a predetermined cycle number for switching. As shown in FIG. 3, N2 can be equal to N1, wherein N1 can be 1000 to 1500, and N2 can be 1000 to 1500. In addition, the method can further comprise repeating said programming the block 200 from the 0^{th} word line WL(0) to the M^{th} word line WL(M) for N1 program-erase cycles and said programming the block 200 from the M^{th} word line WL(M) to the 0^{th} word line WL(0) for N2 program-erase cycles in an alternate manner.

FIG. 4 shows another example of the method according to the disclosure. In this example, a normal program sequence, i.e., the program sequence from the 0^{th} word line WL(0) to the M^{th} word line WL(M), is used in the block 200 at the beginning of life of the memory device 100. The program sequence of the block 200 is switched from from the 0^{th} word line WL(0) to the M^{th} word line WL(M) to from the M^{th} word line WL(M) to the 0^{th} word line WL(0) when a cycle number during the N1 program-erase cycles reaches a predetermined threshold number, such as 1000 to 2000, and particular 1000. In this example, N1 can be larger than or equal to N2. For instance, N1 can be 1000 to 2000, and N2 can be 500 to 1000. The method can further comprise, after said programming the block 200 from the M^{th} word line WL(M) to the 0^{th} word line WL(0) for N2 program-erase cycles, programming the block 200 from the 0^{th} word line to the M^{th} word line WL(M) for N3 program-erase cycles. As shown in FIG. 4, N3 can be equal to N2, wherein N2 can be 500 to 1000, and N3 can be 500 to 1000. In addition, the method can further comprise repeating said programming the block 200 from the M^{th} word line WL(M) to the 0^{th} word line WL(0) for N2 program-erase cycles and said programming the block 200 from the 0^{th} word line WL(0) to the M^{th} word line WL(M) for N3 program-erase cycles in an alternate manner. In other words, after the predetermined threshold number is reached and the first switching is done, the operation to the block 200 is performed in a manner similar to the previous example.

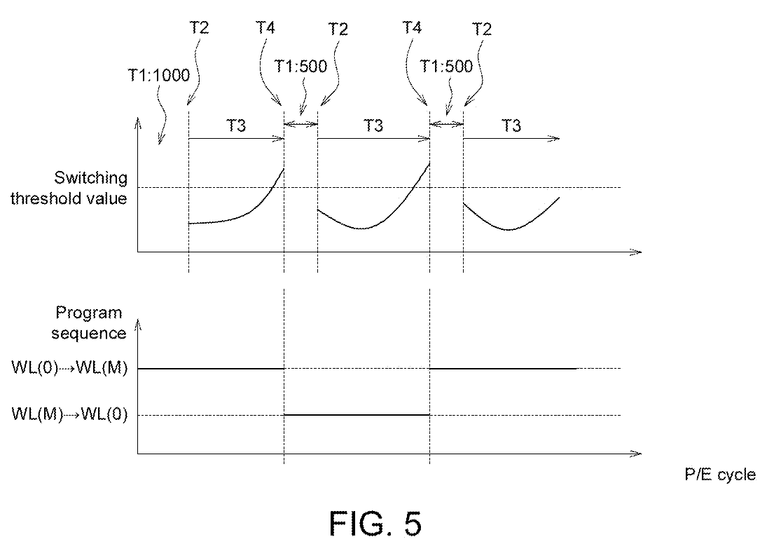

FIG. 5 shows still another example of the method according to the disclosure. In this example, the program sequence of the block 200 is switched based on an error difference between word lines at a side of the0^{th} word line WL(0) and word lines at a side of the M^{th} word line WL(M). As such, the method can further comprise monitoring a difference between a fail bit count (FBC) of a first group of word lines at the side of the 0^{th} word line WL(0) and a fail bit count of a second group of word lines at the side of the m^{th} word line WL(M), and switching the program sequence of the block 200 between from the 0^{th} word line WL(0) to the M^{th} word line WL(M) and from the M^{th} word line WL(M) to the 0^{th} word line WL(0) when the difference is larger than a switching threshold value. The first group of word lines can comprise the 0^{th} word line WL(0) to a4^{th} word line WL(4), and the second group of word lines can comprise a (M-4)^{th} word line WL(M-4) to the M^{th} word line WL(M), but the example is not limited thereto. Similar to the previous examples, the method can comprise repeating said programming the block 200 from the 0^{th} word line WL(0) to the M^{th} word line WL(M) for N1 program-erase cycles and said programming the block 200 from the M^{th} word line WL(M) to the 0^{th} word line WL(0) for N2 program-erase cycles in an alternate manner. In some embodiments, the monitoring can be triggered after a predetermined cycle number of triggering. For instance, at the beginning, the program sequence of the block 200 is from the 0^{th} word line WL(0) to the M^{th} word line WL(M). As shown in FIG. 5, during a first time period T1 of the N1 program-erase cycles, the monitoring is off, until at a time point T2, a predetermined cycle number of triggering, such as 1000, is achieved. At the time point T2, the monitoring is begun. During a following time period T3, the block 200 is monitored. The difference between the fail bit count of the first group of word lines and the fail bit count of the second group of word lines becomes larger with time and finally over the switching threshold value. Then, the program sequence of the block 200 is switched at a time point T4, and the monitoring can be skipped. Similar situations can occur during the next period of said programming the block 200 from the M^{th} word line WL(M) to the 0^{th} word line WL(0) for N2 program-erase cycles and the subsequent periods. However, the predetermined cycle number for triggering for said programming the block 200 from the M^{th} word line WL(M) to the 0^{th} word line WL(0) for N2 program-erase cycles can be smaller than the predetermined cycle number for triggering for said programming the block 200 from the0^{th} word line WL(0) to the M^{th} word line WL(M) for N1 program-erase cycles. For instance, the predetermined cycle number for triggering for said programming the block 200 from the 0^{th} word line WL(0) to the M^{th} word line WL(M) for N1 program-erase cycles is 1000, and the predetermined cycle number for triggering for said programming the block 200 from the M^{th} word line WL(M) to the 0^{th} word line WL(0) for N2 program-erase cycles can be 500.

Based on the above, a method involving programming a block of a memory device with different program sequences is provided in the disclosure. Using the method, the unbalance reliability issue happened in the memory devices typically with open blocks can be alleviate or solved.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A method for operating a memory device, wherein the memory device comprises a 0^{th} word line to a M^{th} word line connected to memory cells of a block, and wherein the method comprises:
programming the block from the 0^{th} word line to the M^{th} word line for N1 program-erase cycles; and
programming the block from the M^{th} word line to the 0^{th} word line for N2 program-erase cycles;
wherein N1 and N2 are positive integers.

2. The method according to claim 1, wherein the memory device is an enterprise SSD.

3. The method according to claim 1, comprising:
switching a program sequence of the block using a controller of the memory device between said programming the block from the 0^{th} word line to the M^{th} word line for N1 program-erase cycles and said programming the block from the M^{th} word line to the 0^{th} word line for N2 program-erase cycles.

4. The method according to claim 3, wherein a frequency of the switching is a part of a firmware in the controller.

5. The method according to claim 4, wherein the firmware comprises two set of operation codes for a program sequence from the 0^{th} word line to the M^{th} word line and a program sequence from the M^{th} word line to the 0^{th} word line, respectively.

6. The method according to claim 1, further comprising:
recording a cycle number during the N1 program-erase cycles in a controller of the memory device during said programming the block from the 0^{th} word line to the M^{th} word line for N1 program-erase cycles and recording a cycle number during the N2 program-erase cycles in the controller during said programming the block from the M^{th} word line to the 0^{th} word line for N2 program-erase cycles, and
switching a program sequence of the block between from the 0^{th} word line to the M^{th} word line and from the M^{th} word line to the 0^{th} word line when the cycle number during the N1 program-erase cycles or the cycle number during the N2 program-erase cycles reaches a predetermined cycle number for switching.

7. The method according to claim 6, comprising:
repeating said programming the block from the 0^{th} word line to the M^{th} word line for N1 program-erase cycles and said programming the block from the M^{th} word line to the 0^{th} word line for N2 program-erase cycles in an alternate manner.

8. The method according to claim 6, wherein N2 is equal to N1.

9. The method according to claim 8, wherein N1 is 1000 to 1500, and N2 is 1000 to 1500.

10. The method according to claim 1, comprising:
switching a program sequence of the block from from the 0^{th} word line to the M^{th} word line to from the M^{th} word line to the 0^{th} word line when a cycle number during the N1 program-erase cycles reaches a predetermined threshold number.

11. The method according to claim 1, wherein N1 is larger than or equal to N2, and the method further comprises:
after said programming the block from the M^{th} word line to the 0^{th} word line for N2 program-erase cycles, programming the block from the 0^{th} word line to the M^{th} word line for N3 program-erase cycles, N3 equal to N2.

12. The method according to claim 11, comprising:
repeating said programming the block from the M^{th} word line to the 0^{th} word line for N2 program-erase cycles and said programming the block from the 0^{th} word line to the M^{th} word line for N3 program-erase cycles in an alternate manner.

13. The method according to claim 11, wherein N1 is 1000 to 2000, N2 is 500 to 1000, and N3 is 500 to 1000.

14. The method according to claim 1, further comprising:
monitoring a difference between a fail bit count of a first group of word lines at a side of the 0^{th} word line and a fail bit count of a second group of word lines at a side of the m^{th} word line; and
switching a program sequence of the block between from the 0^{th} word line to the M^{th} word line and from the M^{th} word line to the 0^{th} word line when the difference is larger than a switching threshold value.

15. The method according to claim 14, wherein the first group of word lines comprises the 0^{th} word line to a 4^{th} word line, and the second group of word lines comprises a (M-4)^{th} word line to the M^{th} word line.

16. The method according to claim 14, comprising:
repeating said programming the block from the 0^{th} word line to the M^{th} word line for N1 program-erase cycles and said programming the block from the M^{th} word line to the 0^{th} word line for N2 program-erase cycles in an alternate manner.

17. The method according to claim 14, wherein the monitoring is triggered after a predetermined cycle number of triggering.

18. The method according to claim 17, wherein the predetermined cycle number for triggering for said programming the block from the M^{th} word line to the 0^{th} word line for N2 program-erase cycles is smaller than the predetermined cycle number for triggering for said programming the block from the 0^{th} word line to the M^{th} word line for N1 program-erase cycles.

19. The method according to claim 17, wherein the predetermined cycle number for triggering for said programming the block from the 0^{th} word line to the M^{th} word line for N1 program-erase cycles is 1000, and the predetermined cycle number for triggering for said programming the block from the M^{th} word line to the 0^{th} word line for N2 program-erase cycles is 500.
